(19) United States
(12) Patent Application Publication
(10) Pub. No.: US 2010/0252109 A1
(43) Pub. Date: Oct. 7, 2010

(54) THIN FILM TYPE SOLAR CELL AND METHOD FOR MANUFACTURING THE SAME

(75) Inventors: Jin Hong, Gyeonggi-do (KR); Jae Ho Kim, Gyeonggi-do (KR); Joung Sik Kim, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/678,043

(22) PCT Filed: Sep. 19, 2008
(86) PCT No.: PCT/KR2008/005536

§ 371 Date: Mar. 12, 2010

(30) Foreign Application Priority Data
Sep. 19, 2007 (KR) 10-2007-0095039
Sep. 20, 2007 (KR) 10-2007-0095600
Sep. 28, 2007 (KR) 10-2007-0097795

(51) Int. Cl. H01L 31/00

(52) U.S. Cl. 136/261

(57) ABSTRACT

A thin film type solar cell and a method for manufacturing the same is disclosed, which can overcome various problems caused by a related art laser-scribing procedure since the thin film type solar cell is divided into a plurality of sub-cells through the use of auxiliary electrode or partition wall, the thin film type solar cell comprising a substrate; a front electrode layer and a cell-dividing part on the substrate; and a rear electrode on the semiconductor layer.

### TECHNICAL FIELD

The present invention relates to a thin film type solar cell, and more particularly, to a thin film type solar cell which is suitable for minimizing a resistance of front electrode.

### BACKGROUND ART

A solar cell with a property of semiconductor converts a light energy into an electric energy.

A structure and principle of the solar cell according to the related art will be briefly explained as follows. The solar cell is formed in a PN-junction structure where a positive(P)-type semiconductor makes a junction with a negative(N)-type semi-conductor. When a solar ray is incident on the solar cell with the PN-junction structure, holes(+) and electrons(−) are generated in the semiconductor owing to the energy of solar ray. By an electric field generated in an PN-junction area, the holes(+) are drifted toward the P-type semiconductor, and the electrons(−) are drifted toward the N-type semiconductor, whereby an electric power is produced with an occurrence of electric potential.

The solar cell can be largely classified into a wafer type solar cell and a thin film type solar cell.

The wafer type solar cell is manufactured through the use of substrate made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer. In this case, since the front electrode corresponds to a solar ray incidence face, the front electrode is made of a transparent conductive material, for example, ZnO. With the large-sized substrate, a resistance is increased in the front electrode made of the transparent conductive material, thereby causing the increase in power loss.

Thus, a method for minimizing the resistance in the front electrode made of the transparent conductive material has been proposed, in which the thin film type solar cell is divided into a plurality of unit cells, and the plurality of unit cells are connected in series.

Hereinafter, a related art method for manufacturing a thin film type solar cell with a plurality of unit cells connected in series will be described with reference to the accompanying drawings.

FIGS. 1A to 1F are cross section views illustrating a related art method for manufacturing a thin film type solar cell with a plurality of unit cells connected in series.

First, as shown in FIG. 1A, a front electrode layer 12 is formed on a substrate 10, wherein the front electrode layer 12 is made of a transparent conductive material, for example, ZnO.

Next, as shown in FIG. 1B, unit front electrodes 12a, 12b and 12c are formed by patterning the front electrode layer 12. This procedure for patterning the front electrode layer 12 may be performed by a laser-scribing procedure.

Next, as shown in FIG. 1C, a semiconductor layer 14 is formed on an entire surface of the substrate 10. The semiconductor layer 14 is formed of a semiconductor material such as silicon, wherein the semiconductor layer 14 has a PIN structure where a positive(P)-type semiconductor layer (hereinafter, referred to as P-layer), an intrinsic(I)-type semiconductor layer (hereinafter, referred to as I-layer), and a negative(N)-type semiconductor layer (hereinafter, referred to as N-layer) are deposited in sequence.

As shown in FIG. 1D, unit semiconductor layers 14a, 14b and 14c are formed by patterning the semiconductor layer 14. The procedure for patterning the semiconductor layer 14 may be performed by the laser-scribing procedure.

Next, as shown in FIG. 1E, a transparent conductive layer 16 and a rear electrode layer 18 are sequentially formed on the entire surface of the substrate 10. The transparent conductive layer 16 is formed of zinc oxide (ZnO), and the rear electrode layer 18 is formed of aluminum (Al).

As shown in FIG. 1F, unit rear electrodes 18a, 18b and 18c are formed by patterning the rear electrode layer 18. At this time, when patterning the rear electrode layer 18, the transparent conductive layer 16 and unit semiconductor layers 14b and 14c, positioned underneath the rear electrode layer 18, are also patterned by the laser-scribing procedure.

According as the solar cell is divided into the plurality of unit cells, and the unit cells are connected in series, the resistance of front electrode is not increased even in the large-sized substrate, thereby preventing the problem of power loss.

However, the related art method for manufacturing the thin film type solar cell necessarily requires the laser-scribing procedure. This may cause the following problems.

First, large amounts of particles may generate due to the performance of laser-scribing procedure. The generated particles may cause the problems such as a contamination of substrate and a short of device.

Second, if laser is excessively supplied to the desired layer due to the inappropriate control of laser irradiation and exposing time, the lower layer positioned underneath the desired layer as well as the desired layer may be scribed together.

Third, the laser-scribing procedure may cause the complicacy in the process for manufacturing the thin film type solar cell. In addition, it is difficult to perform the laser-scribing procedure maintained under atmospheric conditions and other procedures maintained under vacuum conditions in succession.

### DISCLOSURE OF INVENTION

### Technical Problem

Therefore, the present invention has been made in view of the above problems, and it is an object of the present invention to provide a thin film type solar cell and a method for manufacturing the same, which is suitable for realizing a large size without increasing a resistance of front electrode and dividing the thin film type solar cell into a plurality of unit cells.

### Technical Solution

To achieve these objects and other advantages and in accordance with the purpose of the invention, as embodied and broadly described herein, a thin film type solar cell comprises a substrate; a front electrode layer and a cell-dividing part on the substrate; a semiconductor layer on the front electrode layer and the cell-dividing part; and a rear electrode on the semiconductor layer.

At this time, the cell-dividing part is comprised of an auxiliary electrode. In addition, an insulating layer may be additionally formed on the substrate.

The insulating layer may be formed on lateral and upper surfaces of the auxiliary electrode, or may be formed at one lateral side of the auxiliary electrode.

The insulating layer may be formed between each of the auxiliary electrodes, or may be formed in a predetermined pattern with an elliptical-shaped horizontal cross section.

The insulating layer is higher than the auxiliary electrode.

The thin film type solar cell further includes first and second bus lines exposed to the external, wherein the first bus line is connected with the auxiliary electrode at one side of the substrate, and the second bus line is connected with the rear electrode at the other side of the substrate.

The auxiliary electrode is comprised of a plurality of first auxiliary electrodes arranged at fixed intervals in a first direction, and a second auxiliary electrode arranged in a second direction to connect the respective first auxiliary electrodes.

The auxiliary electrode is formed of a predetermined material whose electric conductivity is higher than the front electrode layer.

The cell-dividing part is formed of a partition wall. At this time, the partition wall is formed in a stripe or grating pattern.

The rear electrode is comprised of a plurality of first rear electrodes arranged at fixed intervals in a first direction, and a second rear electrode arranged in a second direction to connect the respective first rear electrodes.

The rear electrode is formed in an area between each of the cell-dividing parts.

Also, a transparent conductive layer is formed between the semiconductor layer and the rear electrode.

The cell-dividing part may be formed on the front electrode layer, or may be formed underneath the front electrode layer.

In another aspect of the present invention, a method for manufacturing a thin film type solar cell comprises forming a front electrode layer and a cell-dividing part on a substrate; forming a semiconductor layer on the front electrode layer and the cell-dividing part; and forming a rear electrode on the semiconductor layer.

The cell-dividing part may be comprised of an auxiliary electrode. At this time, forming an insulating layer on the substrate is additionally performed before forming the semiconductor layer.

The insulating layer may be formed on lateral and upper surfaces of the auxiliary electrode, or may be formed at one lateral side of the auxiliary electrode.

The insulating layer is formed between each of the auxiliary electrodes. At this time, the insulating layer is formed in a predetermined pattern with an elliptical-shaped horizontal cross section.

The insulating layer is higher than the auxiliary electrode.

The step of forming the auxiliary electrode comprises forming a first bus line connected with the auxiliary electrode at one side of the substrate, and the step of forming the rear electrode comprises forming a second bus line connected with the rear electrode at the other side of the substrate, wherein the front electrode layer, the semi-conductor layer, and the rear electrode are not formed on the first bus line, to expose the first bus line to the external.

The step of forming the auxiliary electrode comprises forming a plurality of first auxiliary electrodes arranged at fixed intervals in a first direction, and forming a second auxiliary electrode in a second direction to connect the respective first auxiliary electrodes.

The auxiliary electrode is formed of a material whose electric conductivity is higher than that of the front electrode layer.

The cell-dividing part is comprised of a partition wall, and the partition wall is formed in a stripe or grating pattern.

The step of forming the rear electrode comprises forming a plurality of first rear electrodes arranged at fixed intervals in a first direction, and forming a second rear electrode arranged in a second direction to connect the respective second rear electrodes.

The rear electrode is formed in an area between each of the cell-dividing parts.

The method further includes forming a transparent conductive layer between the semiconductor layer and the rear electrode.

The front electrode layer may be formed on the substrate, and the cell-dividing part may be formed on the front electrode layer. In another way, the cell-dividing part may be formed on the substrate, and the front electrode layer may be formed on the cell-dividing part.

It is to be understood that both the foregoing general description and the following detailed description of the present invention are exemplary and explanatory and are intended to provide further explanation of the invention as claimed.

### Advantageous Effects

The thin film type solar cell according to the present invention and the method for manufacturing the same has the following advantages.

In the related art method for manufacturing the thin film type solar cell, large amount of particles are generated due to performance of laser-scribing procedures. However, the method for manufacturing the thin film type solar cell according to the present invention doesn't require the laser-scribing procedure, whereby the particles are not generated in the method for manufacturing the thin film type solar cell according to the present invention. As a result, the method for manufacturing the thin film type solar cell according to the present invention can avoid various problems caused by the particles, for example, contamination of the substrate, short of the device, scribing for the undesired layer, the complicated process, and impossibility of performing the consecutive procedure.

According as the thin film type solar cell according to the present invention is divided into the plurality of unit cells through the use of auxiliary electrode or partition wall instead of the related art laser-scribing method, it is possible to prevent the resistance of front electrode layer from being increased even in the large-sized device.

Also, the insulating layer as well as the auxiliary electrode is formed additionally, thereby preventing the problems generated in the interface between the auxiliary electrode and the semiconductor layer, and realizing the precise division in the solar cell. Additionally, the insulating layer makes it possible to increase the entire size of the semiconductor layer and improve the light-capturing efficiency.

### BRIEF DESCRIPTION OF THE DRAWINGS

FIGS. 1A to 1F are cross section views illustrating a method for manufacturing a thin film type solar cell according to the related art;

FIG. 2 is a cross section view illustrating a thin film type solar cell according to the first embodiment of the present invention;

FIG. 3 is a cross section view illustrating a thin film type solar cell according to the second embodiment of the present invention;

FIG. 4 is a cross section view illustrating a thin film type solar cell according to the third embodiment of the present invention;

FIG. 5 is a cross section view illustrating a thin film type solar cell according to the fourth embodiment of the present invention;

FIG. 6 is a cross section view illustrating a thin film type solar cell according to the fifth embodiment of the present invention;

FIG. 7 is a cross section view illustrating a thin film type solar cell according to the sixth embodiment of the present invention;

FIGS. 8A to 8D are plan views illustrating various types of auxiliary electrode according to the present invention;

FIG. 9 is a plan view illustrating one type of rear electrode according to the present invention;

FIGS. 10A to 10D are plan views illustrating various types of auxiliary electrode and insulating layer according to the present invention;

FIGS. 11A to 11C are plan views illustrating various types of partition wall according to the present invention, and FIG. 11D is a plan view illustrating one type of rear electrode according to the present invention;

FIGS. 12A to 12E are cross section views illustrating a method for manufacturing a thin film type solar cell according to the first embodiment of the present invention;

FIGS. 13A to 13F are cross section views illustrating a method for manufacturing a thin film type solar cell according to the second embodiment of the present invention;

FIGS. 14A to 14F are cross section views illustrating a method for manufacturing a thin film type solar cell according to the third embodiment of the present invention;

FIGS. 15A to 15E are cross section views illustrating a method for manufacturing a thin film type solar cell according to the fourth embodiment of the present invention;

FIGS. 16A to 16E are cross section views illustrating a method for manufacturing a thin film type solar cell according to the fifth embodiment of the present invention; and

FIGS. 17A to 17E are cross section views illustrating a method for manufacturing a thin film type solar cell according to the sixth embodiment of the present invention.

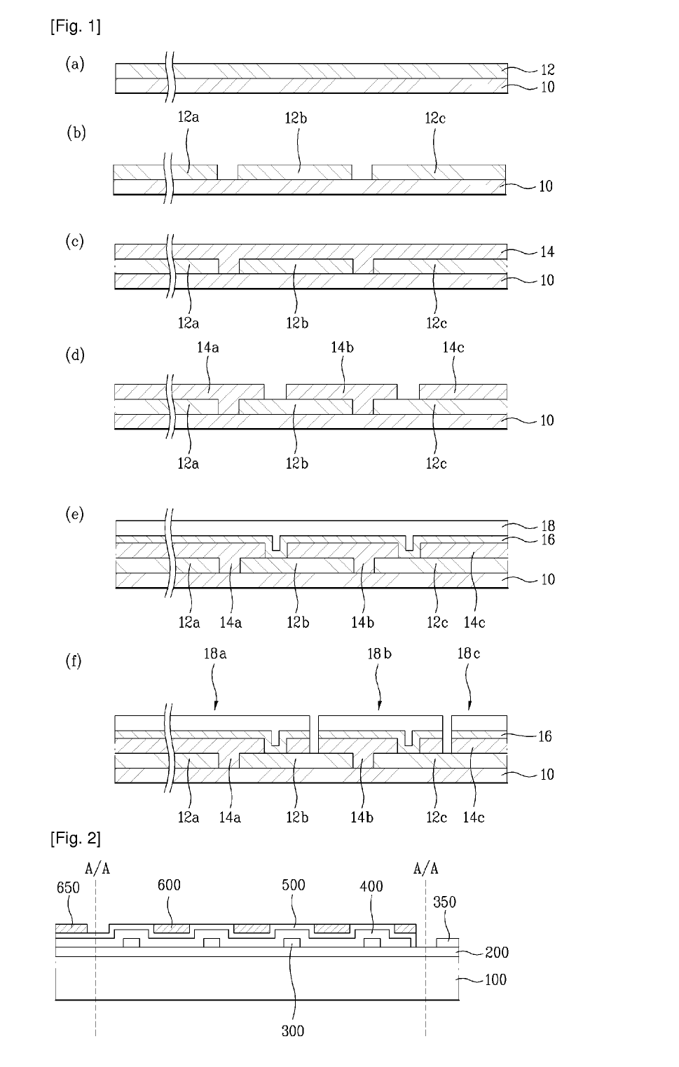

For reference, all cross section views are taken along I-I of the corresponding plan views.

### BEST MODE FOR CARRYING OUT THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

<Thin Film Type Solar Cell>

### FIRST EMBODIMENT

FIG. 2 is a cross section view illustrating a thin film type solar cell according to the first embodiment of the present invention.

As shown in FIG. 2, the thin film type solar cell according to the first embodiment of the present invention includes a substrate 100, a front electrode layer 200, an auxiliary electrode 300, a semiconductor layer 400, a transparent conductive layer 500, and a rear electrode 600.

At this time, the substrate 100 may be formed of glass or transparent plastic. The transparent conductive layer 200 is formed on the substrate 100, wherein the transparent conductive layer 200 is formed of a transparent conductive material such as ZnO, ZnO:B, ZnO:Al, ZnO:H, SnO₂, SnO₂:F, or ITO (Indium Tin Oxide) by sputtering or MOCVD (Metal Organic Chemical Vapor Deposition).

Also, the front electrode layer 200 corresponds to a solar ray incidence face, so that it is important for the front electrode layer 200 to transmit solar ray into the inside of solar cell with the minimized loss. For this, a texturing process may be additionally performed to the front electrode layer 200. Through the texturing process, a surface of material layer becomes uneven, that is, texture structure, by an etching process using photolithography, an anisotropic etching process using a chemical solution, or a mechanical scribing process. According as the texturing process is performed to the front electrode layer 200, a solar-ray reflection ratio on the front electrode layer 200 of the solar cell is decreased and a solar-ray absorbing ratio in the solar cell is increased owing to a dispersion of solar ray, thereby improving the solar cell efficiency.

The auxiliary electrode 300, formed on the front electrode layer 200, divides the thin film type solar cell into a plurality of sub-cells. The auxiliary electrode 300 is formed in predetermined patterns on the front electrode layer 200, wherein the predetermined patterns are electrically connected with one another.

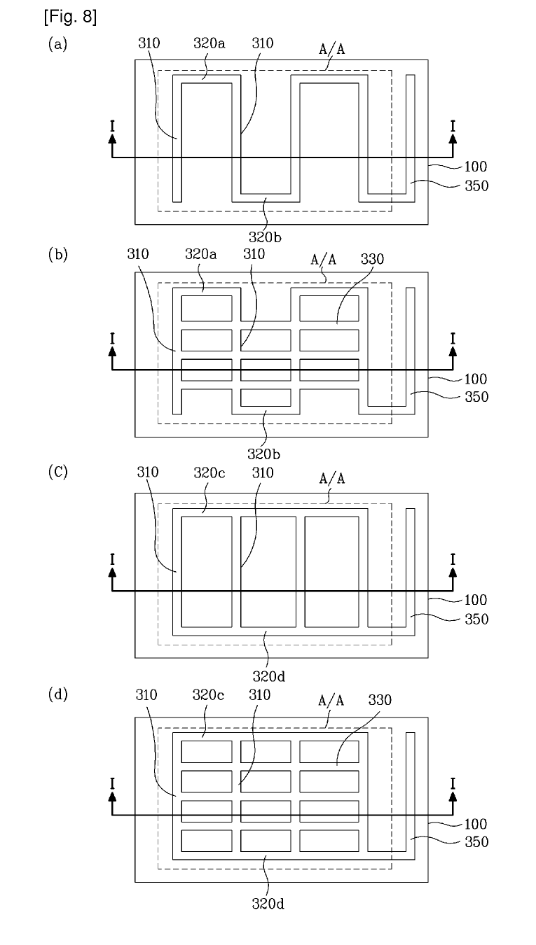

The various patterns of auxiliary electrode 300 are described with reference to FIGS. 8A to 8D. FIG. 8A is a plan view illustrating one type of the auxiliary electrode 300, wherein the auxiliary electrode 300 of FIG. 8A is comprised of first auxiliary electrodes 310 and second auxiliary electrodes 320a and 320b on the substrate 100. The first auxiliary electrodes 310 are arranged at fixed intervals in a first direction (for example, a short-side direction of the substrate 100), and the second auxiliary electrodes 320a and 320b are arranged in a second direction (for example, a long-side direction of the substrate 100, which is perpendicular to the first direction), wherein the first auxiliary electrodes 310 are electrically connected by the second auxiliary electrodes 320a and 320b. In more detail, the second auxiliary electrodes 320a and 320b are arranged alternately, that is, the second auxiliary electrode 320a connects one end of the first auxiliary electrodes 310 and the second auxiliary electrode 320b connects the other end of the first auxiliary electrodes 310, as shown in FIG. 8A.

A first bus line 350 is connected with the auxiliary electrode 300. The first bus line 350 connects the thin film type solar cell with an external circuit, wherein the first bus line 350 is formed at one side of the substrate 100 in the periphery of active area (A/A) of thin film type solar cell.

Through the first bus line 350, the thin film type solar cell is connected with the external circuit. Thus, any other components are not provided on the first bus line 350, as shown in FIG. 2, to thereby expose the first bus line 350 to the external.

FIG. 8B is a plan view illustrating another type of the auxiliary electrode 300. Except that third auxiliary electrodes 330 are provided additionally, the auxiliary electrode of FIG. 8B is identical in structure to the auxiliary electrode of FIG. 8A. At this time, the third auxiliary electrodes 330 intersect the first auxiliary electrodes 310, wherein the third auxiliary electrodes 330 are arranged at fixed intervals. According as the third auxiliary electrodes 330 are provided additionally, the auxiliary electrode shown in FIG. 8B entirely has a grating shape so that the thin film type solar cell is provided with more sub-cells divided.

FIG. 8C is a plan view illustrating a third type of the auxiliary electrode 300. Except second auxiliary electrodes 320c and 320d, the auxiliary electrode of FIG. 8C is identical in structure to the auxiliary electrode of FIG. 8A. As shown in FIG. 8C, the second auxiliary electrodes 320c and 320d are comprised of one pattern 320c which connects one end of each of the first auxiliary electrodes 310, and the other pattern 320d which connects the other end of each of the first auxiliary electrodes 310.

FIG. 8D is a plan view illustrating the other type of the auxiliary electrode 300. According as third auxiliary electrodes 330 are provided additionally, the auxiliary electrode of FIG. 8D is identical in structure to the auxiliary electrode of FIG. 8C. The third auxiliary electrodes 330 intersect the first auxiliary electrodes 310, wherein the third auxiliary electrodes 330 are arranged at fixed intervals. According as the third auxiliary electrodes 330 are provided additionally, the auxiliary electrode shown in FIG. 8D entirely has a grating shape so that the thin film type solar cell is provided with more sub-cells divided.

The auxiliary electrodes 300 may be formed in the various shapes shown in FIGS. 8A to 8D, however, the auxiliary electrodes 300 are not limited to the aforementioned shapes shown in FIGS. 8A to 8D.

The auxiliary electrode 300 and the first bus line 350 connected with the auxiliary electrode 300 may be formed of metal such as Ag, Al, Ag⁺Al, Ag⁺Mg, Ag⁺Mn, Ag⁺Sb, Ag⁺Zn, Ag⁺Mo, Ag⁺Ni, Ag⁺Cu, or Ag⁺Al⁺Zn by a screen printing method, inkjet printing method, gravure printing method, or micro-contact printing method. In the case of the screen printing method, a material is transferred to a predetermined body through the use of squeeze. The inkjet printing method sprays a material onto a pre-determined body through the use of inkjet, to thereby form a predetermined pattern thereon. In the case of the gravure printing method, a material is coated on an intaglio plate, and then the coated material is transferred to a predetermined body, thereby forming a predetermined pattern on the predetermined body. The micro-contact printing method forms a predetermined pattern of material on a predetermined body through the use of predetermined mold.

Preferably, the auxiliary electrode 300 is formed of a material whose electric conductivity is higher than that of the front electrode layer 200, to thereby minimize the power loss caused due to the increased resistance.

The semiconductor layer 400 is formed on the front electrode layer 200 and the auxiliary electrode 300. Also, the semiconductor layer 400 is not formed on the first bus line 350 so as to expose the first bus line 350 to the external. The semiconductor layer 400 may be formed of a silicon-based semiconductor material by a plasma CVD method, wherein the silicon-based semiconductor material may be amorphous silicon (a-Si:H) or microcrystalline silicon (uc-Si:H).

The semiconductor layer 400 may be formed in a PIN structure where a P-layer, an I-layer, and an N-layer are deposited in sequence. At this time, holes and electrons are generated by the solar ray, and the generated holes and electrons are collected in the respective P-layer and N-layer of the semiconductor layer 400. In order to improve the efficiency in collection of the holes and electrons, preferably, the PIN structure is preferable than a PN structure which is comprised of the P-layer and N-layer. If forming the semiconductor layer 400 with the PIN structure, depletion occurs in the I-layer by the P-layer and the N-layer, whereby an electric field is generated therein. Also, the holes and electrons generated by the solar ray are drifted by the electric field, and are then collected in the respective P-layer and N-layer.

In the meantime, if the semiconductor layer 400 is formed in the PIN structure, it is preferable to form the P-layer firstly, and to form the I-layer and N-layer secondly. This is because a drift mobility of the hole is less than a drift mobility of the electron. In order to maximize the collection efficiency by the incident ray, the P-layer is formed adjacent to the solar ray incidence face.

The transparent conductive layer 500 is formed on the semiconductor layer 400. However, the transparent conductive layer 500 is not formed on the first bus line 350 so as to expose the first bus line 350 to the external. The transparent conductive layer 500 may be formed of a transparent conductive material such as ZnO, ZnO:B, ZnO:Al, ZnO:H, or Ag by sputtering or MOCVD (Metal Organic Chemical Vapor Deposition).

The transparent conductive layer 500 may be omitted. However, it is preferable that the transparent conductive layer 500 be formed so as to improve the solar cell efficiency. That is, when forming the transparent conductive layer 500, the solar ray passes through the semiconductor layer patterns 400, and then passes through the transparent conductive layer patterns 500. In this case, the solar ray passing through the transparent conductive layer 500 is dispersed at different angles. Thus, after the solar ray is reflected on the rear electrodes 600, the ratio of solar ray re-incidence is increased on the semiconductor layer 400.

The rear electrodes 600 are formed in the predetermined patterns on the transparent conductive layer 500, wherein the predetermined patterns of the rear electrode 600 are connected electrically.

The predetermined patterns of the rear electrode 600 are shown in FIG. 9. As shown in FIG. 9, the rear electrode 600 may be comprised of the first rear electrodes 610 and the second rear electrodes 620a and 620b.

The first rear electrodes 610 are arranged at fixed intervals in a first direction (for example, a short-side direction of the substrate 100), and the second rear electrodes 620a and 620b are arranged at fixed intervals in a second direction (for example, a long-side direction of the substrate 100, which is perpendicular to the first direction), wherein the first rear electrodes 610 are electrically connected by the second rear electrodes 620a and 620b. In more detail, the second rear electrodes 620a and 620b are arranged alternately, that is, the second rear electrode 620a connects one end of the first rear electrodes 610, and the second rear electrode 620b connects the other end of the first rear electrode 610, as shown in FIG. 9.

A second bus line 650 is connected with the rear electrode 600. The second bus line 650 is formed at the other side of the substrate 100 in the periphery of active area (A/A) of thin film type solar cell. That is, through the first and second bus lines 350 and 650, the thin film type solar cell is connected with the external circuit.

The first bus line 350 is formed at one side of the substrate 100, and the second bus line 650 is formed at the other side of the substrate 100, whereby the first and second bus lines 350 and 650 respectively serve as the positive(+) and negative(−) polarities of the thin film type solar cell.

FIG. 9 illustrates one type of the rear electrode 600. However, the rear electrode 600 according to the present invention is not limited to the aforementioned shape of FIG. 9.

The rear electrode 600 may be formed in an area between the auxiliary electrodes 300.

The rear electrode 600 and the second bus line 650 connected with the rear electrode 600 may be formed of metal such as Ag, Al, Ag⁺Al, Ag⁺Mg, Ag⁺Mn, Ag⁺Sb, Ag⁺Zn, Ag⁺Mo, Ag⁺Ni, Ag⁺Cu, or Ag⁺Al⁺Zn by a screen printing method, inkjet printing method, gravure printing method, or micro-contact printing method.

### SECOND EMBODIMENT

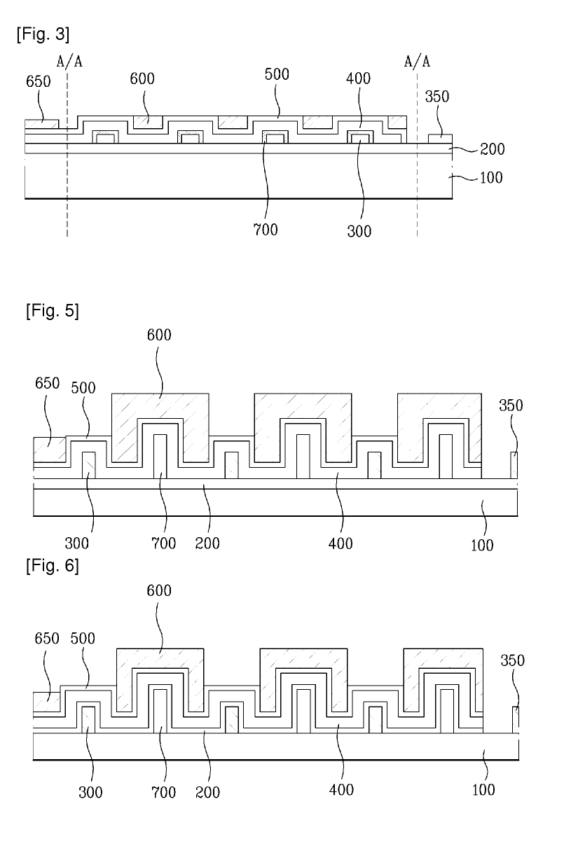

FIG. 3 is a cross section view illustrating a thin film type solar cell according to the second embodiment of the present invention.

Except that an insulating layer 700 is provided additionally, the thin film type solar cell according to the second embodiment of the present invention is identical in structure to the thin film type solar cell according to the first embodiment of the present invention, whereby the same reference numbers will be used throughout the drawings to refer to the same or like parts, and the detailed explanation for the same parts will be omitted.

The thin film type solar cell according to the second embodiment of the present invention additionally includes the insulating layer 700, wherein the insulating layer 700 covers the auxiliary electrode 300, that is, the insulating layer 700 is formed on lateral and upper surfaces of the auxiliary electrode 300. In more detail, the insulating layer 700 is formed on the lateral and upper surfaces of first auxiliary electrode 310, second auxiliary electrodes 320a, 320b, 320c and 320d, and third auxiliary electrode 330 shown in FIGS. 8A to 8D.

The insulating layer 700 prevents the auxiliary electrode 300 from being in direct contact with the semiconductor layer 400, thereby preventing failures in the interface between the auxiliary electrode 300 and the semiconductor layer 400.

The insulating layer 700 may be additionally formed in the periphery of active area (A/A) of thin film type solar cell. In this case, in order to expose the first bus line 350 to the external, the insulating layer 700 is not formed on the first bus line 350.

The insulating layer 800 is formed of an insulating material such as SiO₂, TiO₂, SiNₓ, SiON, or polymer by a screen printing method, inkjet printing method, gravure printing method, or micro-contact printing method.

### THIRD EMBODIMENT

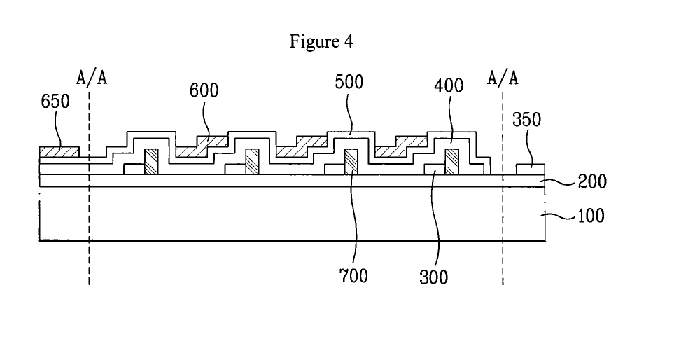

FIG. 4 is a cross section view illustrating a thin film type solar cell according to the third embodiment of the present invention.

Except that an insulating layer 700 is provided additionally, the thin film type solar cell according to the third embodiment of the present invention is identical in structure to the thin film type solar cell according to the first embodiment of the present invention, whereby the same reference numbers will be used throughout the drawings to refer to the same or like parts, and the detailed explanation for the same parts will be omitted.

The thin film type solar cell according to the third embodiment of the present invention additionally includes the insulating layer 700, wherein the insulating layer 700 is formed at one lateral side of the auxiliary electrode 300. In more detail, the insulating layer 700 is formed at one lateral side of the first auxiliary electrode 310 shown in FIGS. 8A to 8D, wherein the insulating layer 700 is higher than the first auxiliary electrode 310. If needed, the insulating layer 700 may be formed at one lateral side of the second auxiliary electrode 320a, 320b, 320c and 320d and/or third auxiliary electrode 330, wherein the insulating layer 700 is higher than the second or third auxiliary electrode.

According as the insulating layer 700 is formed at one lateral side of the auxiliary electrode 300 and becomes higher than the auxiliary electrode 300, it enables the more precise division of sub-cells. In addition, the solar ray may be reflected or dispersed by the insulating layer 700, thereby improving light-capturing efficiency.

The insulating layer 700 may be additionally formed in the periphery of active area (A/A) of thin film type solar cell. In this case, in order to expose the first bus line 350 to the external, the insulating layer 700 is not formed on the first bus line 350.

### FOURTH EMBODIMENT

FIG. 5 is a cross section view illustrating a thin film type solar cell according to the fourth embodiment of the present invention.

Except that an insulating layer 700 is provided additionally, the thin film type solar cell according to the fourth embodiment of the present invention is identical in structure to the thin film type solar cell according to the first embodiment of the present invention, whereby the same reference numbers will be used throughout the drawings to refer to the same or like parts, and the detailed explanation for the same parts will be omitted.

The thin film type solar cell according to the fourth embodiment of the present invention additionally includes the insulating layer 700, wherein the insulating layer 700 is formed between each of the auxiliary electrodes 300 on the front electrode layer 200.

In order to prevent a light-transmitting ratio from being lowered, the insulating layer 700 is formed of a transparent insulating material such as SiO₂, TiO₂, SiNₓ, SiON, or polymer.

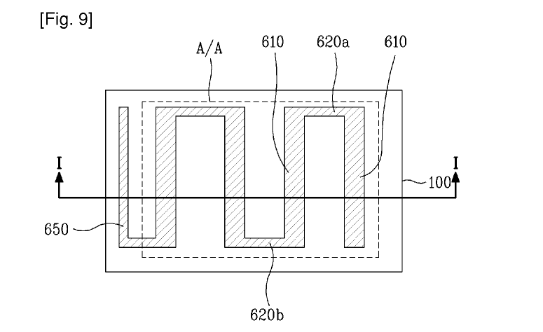

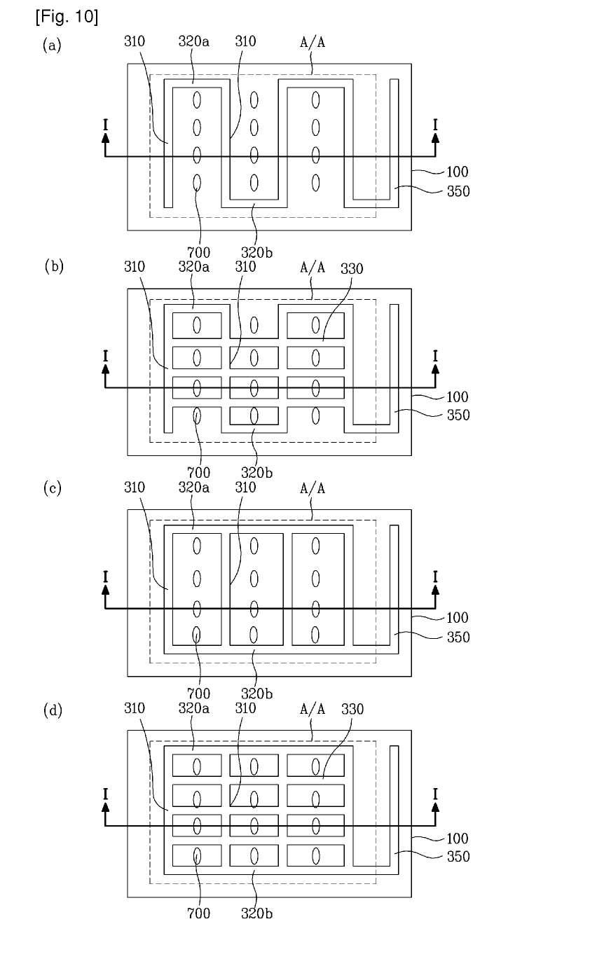

As shown in FIGS. 10A to 10D, it is preferable that the insulating layer 700 and the auxiliary electrode 300 be alternately arranged at fixed intervals along one direction (for example, the longitudinal direction of the substrate).

The insulating layer 700 enhances the solar cell efficiency by increasing an entire size of the semiconductor layer 400. That is, if forming the insulating layer 700, it is possible to increase the entire size of the semiconductor layer 400 provided on the insulating layer 700, thereby improving the solar cell efficiency. In order to increase the entire size of the semiconductor layer 400, it is preferable that the insulating layer 700 be higher than the auxiliary electrode 300.

Also, the insulating layer 700 improves the light-capturing ratio. That is, if forming the insulating layer 700, the light transmitted through the front electrode layer 200 positioned underneath the insulating layer 700 is refracted and dispersed at different angles, whereby the light-capturing efficiency improves. As a result, the improved light-capturing efficiency enables improvement of light-absorbing efficiency.

Preferably, as shown in FIGS. 10A to 10D, predetermined patterns of the insulating layer 700 serving the aforementioned functions are arranged at fixed intervals, wherein each pattern is formed of an insulating-material pattern with an elliptical-shaped horizontal cross section, preferably. Even though the insulating layer 700 is formed of the transparent insulating material, the light-transmitting ratio may be lowered with the increased horizontal cross section of the insulating layer 700. Thus, it is preferable that the insulating layer 700 have the small-sized horizontal cross section. However, the insulating layer is not limited to the aforementioned shape and pattern. Instead of arranging the patterns of insulating layer at fixed intervals, the insulating material may be provided along a straight line. Also, the horizontal cross section of the insulating layer pattern may be a triangle, a polygon such as a quadrangle, or a circle.

As shown in FIG. 5, the rear electrode 600 may be formed on the predetermined portion between each of the auxiliary electrodes 300, that is, the portion on the insulating layer 700. The rear electrode 600 is not formed on the auxiliary electrode 300. This is because the area with the auxiliary electrode 300 has the relatively inferior cell efficiency. That is, there is no requirement for providing the rear electrode 600 on the auxiliary electrode 300, thereby resulting in reduction of a paste cost for forming the rear electrode 600. However, if needed, the rear electrode 600 may be provided on the auxiliary electrode 300.

### FIFTH EMBODIMENT

FIG. 6 is a cross section view illustrating a thin film type solar cell according to the fifth embodiment of the present invention.

Except that the front electrode layer 200, auxiliary electrode 300 and insulating layer 700 are changed in their positions, the thin film type solar cell according to the fifth embodiment of the present invention is identical in structure to the thin film type solar cell according to the fourth embodiment of the present invention, whereby the same reference numbers will be used throughout the drawings to refer to the same or like parts, and the detailed explanation for the same parts will be omitted.

In the thin film type solar cell according to the fifth embodiment of the present invention, the front electrode layer 200 is formed on the auxiliary electrode 300 and insulating layer 700. In comparison to the thin film type solar cell according to the fourth embodiment of the present invention where the front electrode layer 200 is formed on the substrate 100, the thin film type solar cell according to the fifth embodiment of the present invention can realize higher efficiency.

In the thin film type solar cell according to the fifth embodiment of the present invention, the front electrode layer 200 is formed underneath the semiconductor layer 400, whereby the insulating layer 700 is not interposed between the front electrode layer 200 and the semiconductor layer 400. That is, the thin film type solar cell according to the fifth embodiment of the present invention can realize higher efficiency than the thin film type solar cell with the insulating layer 700 interposed between the front electrode layer 200 and the semiconductor layer 400 according to the fourth embodiment of the present invention.

In the thin film type solar cells according to the first, second and third embodiments of the present invention, the front electrode layer 200 may be formed on the auxiliary electrode 300, or the front electrode layer 200 may be formed on the auxiliary electrode 300 and insulating layer 700.

### SIXTH EMBODIMENT

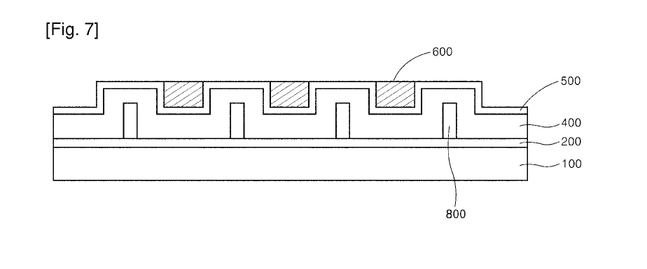

FIG. 7 is a cross section view illustrating a thin film type solar cell according to the sixth embodiment of the present invention.

The thin film type solar cell according to the first embodiment of the present invention is provided with the plurality of sub-cells divided through the use of auxiliary electrode 300. In the meantime, the thin film type solar cell according to the sixth embodiment of the present invention is provided with the plurality of sub-cells divided through the use of partition wall 800. That is, the substrate 100, front electrode layer 200, semiconductor layer 400, transparent conductive layer 500, and rear electrode 600 provided in the thin film type solar cell according to the sixth embodiment of the present invention are identical to those provided in the thin film type solar cell according to the first embodiment of the present invention.

The partition wall 800 is formed on the front electrode layer 200, wherein the partition wall 800 has such a height as to divide the solar cell into at least two unit cells.

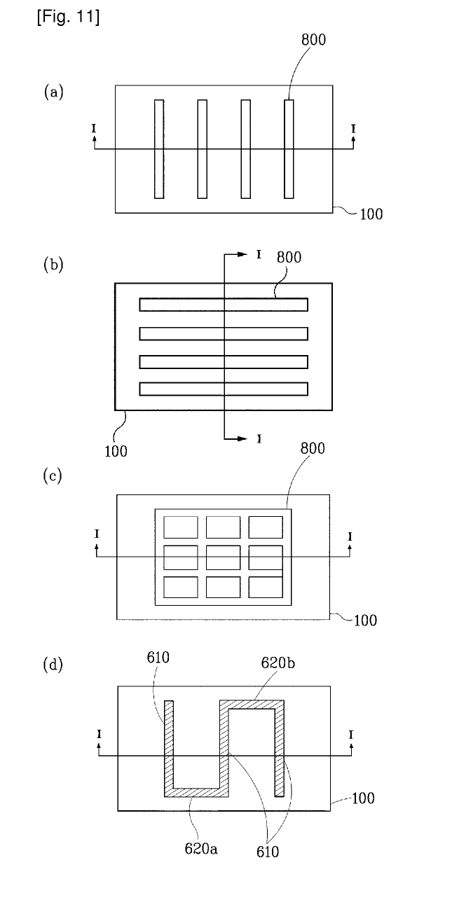

The partition wall 800 is provided in a repetitive pattern to divide the solar cell into the plurality of unit cells. In more detail, as shown in FIGS. 11A and 11B, the partition wall 800 may be formed in a stripe pattern. As shown in FIG. 11C, the partition wall 800 may be formed in a grating pattern.

FIGS. 11A to 11C exemplary illustrate the stripe or grating pattern. However, the partition wall 800 according to the present may vary in shape.

Preferably, the partition wall 800 is formed of a transparent insulating material such as SiO₂, TiO₂, SiNₓ, SiON, or polymer, so as to prevent the light-transmitting ratio from being lowered.

The partition wall 800 may be formed through the use of a screen printing method, inkjet printing method, gravure printing method, or micro-contact printing method.

The rear electrode 600 is formed between each of the partition walls 800.

The rear electrode 600 is formed in the predetermined patterns on the transparent conductive layer 500, wherein the predetermined patterns are connected electrically. That is, as shown in FIG. 11D, the predetermined patterns of rear electrode 600 may be comprised of first rear electrodes 610, and second rear electrodes 620a and 620b provided on the substrate 100.

The front electrode layer 200 may be firstly formed on the substrate 100, and then the partition wall 800 may be formed on the front electrode layer 200. Instead, the partition wall 800 may be firstly formed on the substrate 100, and the front electrode layer 200 may be formed on the partition wall 800.

<Method for Manufacturing Thin Film Type Solar Cell>

### FIRST EMBODIMENT

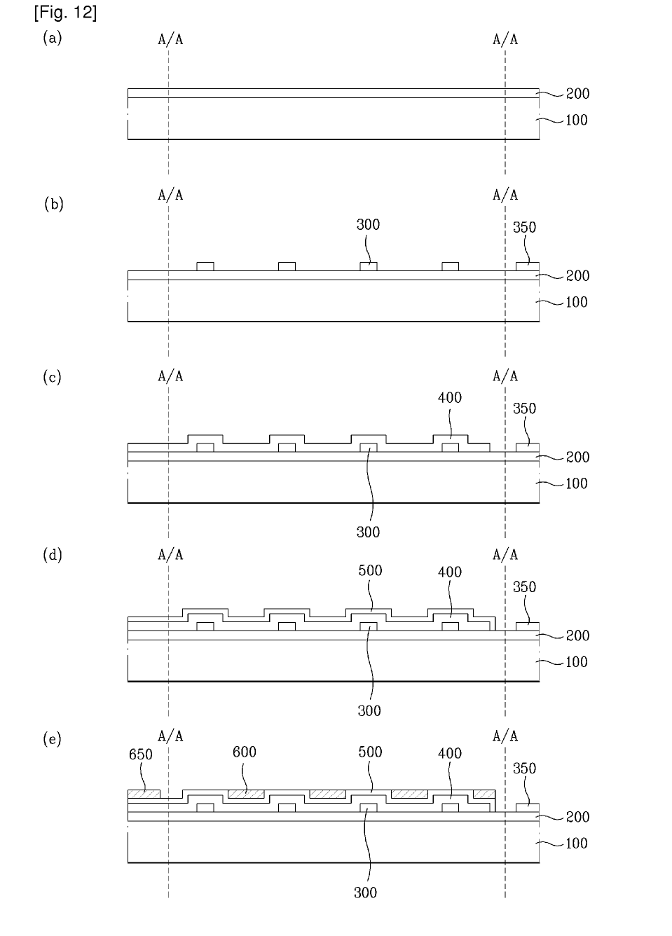

FIGS. 12A to 12E are cross section views illustrating a method for manufacturing a thin film type solar cell according to the first embodiment of the present invention.

First, as shown in FIG. 12A, the front electrode layer 200 is formed on the substrate 100.

At this time, the substrate 100 may be formed of glass or transparent plastic. The transparent conductive layer 200 may be formed of the transparent conductive material such as ZnO, ZnO:B, ZnO:Al, ZnO:H, SnO₂, SnO₂:F, or ITO (Indium Tin Oxide) by sputtering or MOCVD (Metal Organic Chemical Vapor Deposition).

The front electrode layer 200 may have the uneven surface through the texturing process.

As shown in FIG. 12B, the auxiliary electrode 300 is formed on the front electrode layer 200.

The auxiliary electrode 300 and the first bus line 350 are formed at the same time. At this time, the auxiliary electrode 300 is formed within the active area (A/A) of the thin film type solar cell, and the first bus line 350 is formed in the periphery of the active area (A/A).

The auxiliary electrode 300 and the first bus line 350 connected with the auxiliary electrode 300 are formed of metal such as Ag, Al, Ag⁺Al, Ag⁺Mg, Ag⁺Mn, Ag⁺Sb, Ag⁺Zn, Ag⁺Mo, Ag⁺Ni, Ag⁺Cu, or Ag⁺Al⁺Zn by the screen printing method, inkjet printing method, gravure printing method, or micro-contact printing method.

As shown in FIG. 12C, the semiconductor layer 400 is formed on the front electrode layer 200 and auxiliary electrode 300.

The semiconductor layer 400 may be formed in the PIN structure by sequentially depositing the P-layer, I-layer, and N-layer through the plasma CVD method using the silicon-based semiconductor material.

The semiconductor layer 400 is not formed on the first bus line 350. For this, the plasma CVD method is performed while masking the area over the first bus line 350 with a shadow mask, whereby the P-layer, I-layer and N-layer are deposited in sequence.

As shown in FIG. 12D, the transparent conductive layer 500 is formed on the semiconductor layer 400. The transparent conductive layer 500 is formed of the transparent conductive material such as ZnO, ZnO:B, ZnO:Al, ZnO:H, or Ag by sputtering or MOCVD (Metal Organic Chemical Vapor Deposition).

The transparent conductive layer 500 is not formed on the first bus line 350. For this, the sputtering or MOCVD method is performed while masking the area over the first bus line 350 with a shadow mask, whereby the transparent conductive layer is formed.

It is possible to omit the transparent conductive layer 500.

As shown in FIG. 12E, the rear electrode 600 is formed on the transparent conductive layer 500, thereby completing the thin film type solar cell according to the first embodiment of the present invention.

The rear electrode 600 and the second bus line 650 connected with the rear electrode 600 may be formed at the same time. At this time, the rear electrode 600 is formed within the active area (A/A) of the thin film type solar cell, and the second bus line 650 is formed in the periphery of the active area (A/A).

The rear electrode 600 and the second bus line 650 connected with the rear electrode 600 are formed of metal such as Ag, Al, Ag⁺Al, Ag⁺Mg, Ag⁺Mn, Ag⁺Sb, Ag⁺Zn, Ag⁺Mo, Ag⁺Ni, Ag⁺Cu, or Ag⁺Al⁺Zn by the screen printing method, inkjet printing method, gravure printing method, or micro-contact printing method.

### SECOND EMBODIMENT

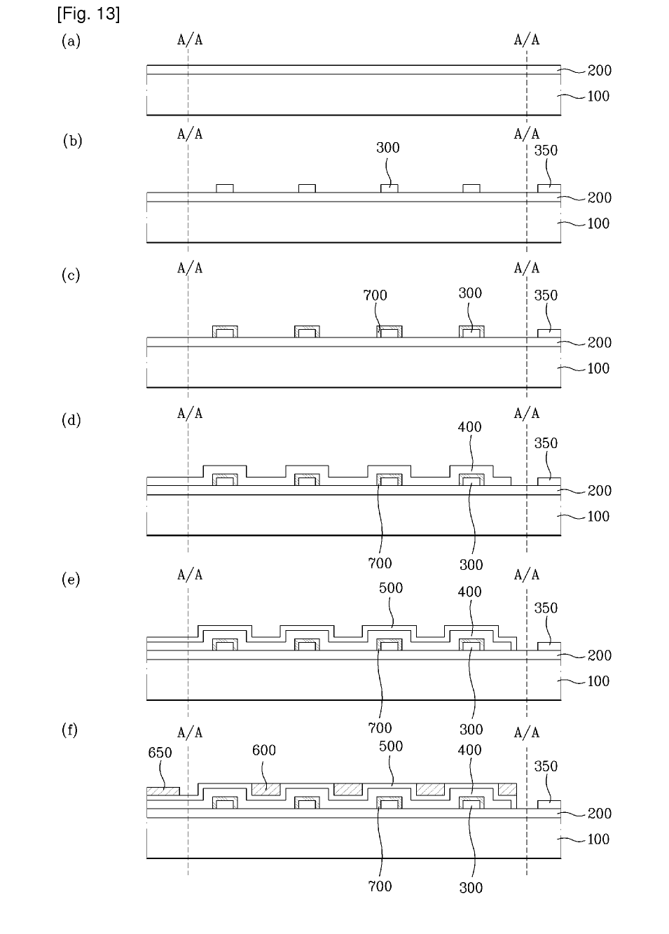

FIGS. 13A to 13F are cross section views illustrating a method for manufacturing a thin film type solar cell according to the second embodiment of the present invention.

First, as shown in FIG. 13A, the front electrode layer 200 is formed on the substrate 100.

Then, as shown in FIG. 13B, the auxiliary electrode 300 and the first bus line 350 connected with the auxiliary electrode 300 are formed on the front electrode layer 200.

As shown in FIG. 13C, the insulating layer 700 covers the auxiliary electrode 300, that is, the insulating layer 700 is formed on the lateral and upper surfaces of the auxiliary electrode 300.

In more detail, the insulating layer 700 is formed on the lateral and upper surfaces of first auxiliary electrode 310, second auxiliary electrodes 320a, 320b, 320c and 320d, and third auxiliary electrode 330 shown in FIGS. 8A to 8D.

The insulating layer 700 may be formed of the insulating material such as SiO₂, TiO₂, SiNₓ, SiON, or polymer by the screen printing method, inkjet printing method, gravure printing method, or micro-contact printing method.

The insulating layer 700 may be additionally formed in the periphery of active area (A/A) of thin film type solar cell. In this case, the insulating layer 700 is not formed on the first bus line 350.

As shown in FIG. 13D, the semiconductor layer 400 is formed on the front electrode layer 200, the auxiliary electrode 300, and the insulating layer 700.

As shown in FIG. 13E, the transparent conductive layer 500 is formed on the semiconductor layer 400.

Then, as shown in FIG. 13F, the rear electrode 600 and the second bus line 650 are formed on the transparent conductive layer 500, thereby completing the thin film type solar cell according to the second embodiment of the present invention.

### THIRD EMBODIMENT

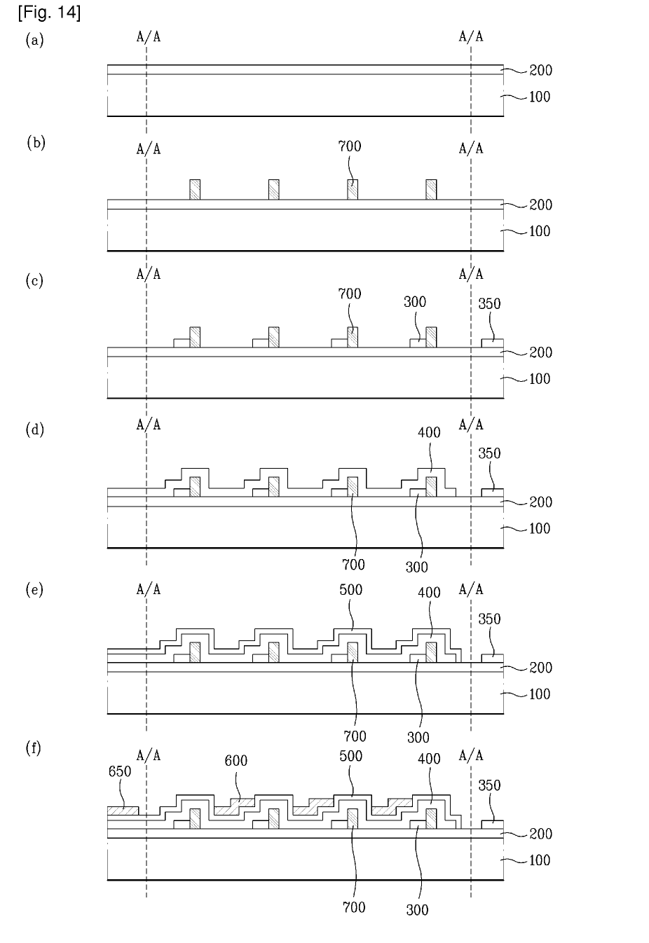

FIGS. 14A to 14F are cross section views illustrating a method for manufacturing a thin film type solar cell according to the third embodiment of the present invention.

First, as shown in FIG. 14A, the front electrode layer 200 is formed on the substrate 100.

Next, as shown in FIG. 14B, the insulating layer 700 is formed on the front electrode layer 200.

The insulating layer 700 is positioned at one side of the auxiliary electrode formed during the procedure of FIG. 14C. At this time, the insulating layer 700 is formed such that the insulating layer 700 becomes higher than the auxiliary electrode 300.

As shown in FIG. 14C, the auxiliary electrode 300 and the first bus line 350 connected with the auxiliary electrode 300 are formed on the front electrode layer 200.

The auxiliary electrode 300 is positioned next to the insulating layer 700.

In the meantime, the auxiliary electrode 300 and the first bus line 350 are firstly formed, and then the insulating layer 700 is formed secondly.

Then, as shown in FIG. 14D, the semiconductor layer 400 is formed on the auxiliary electrode 300 and the insulating layer 700.

As shown in FIG. 14E, the transparent conductive layer 500 is formed on the semiconductor layer 400.

Then, as shown in FIG. 14F, the rear electrode 600 and the second bus line 650 are formed on the transparent conductive layer 500, thereby completing the thin film type solar cell according to the third embodiment of the present invention.

### FOURTH EMBODIMENT

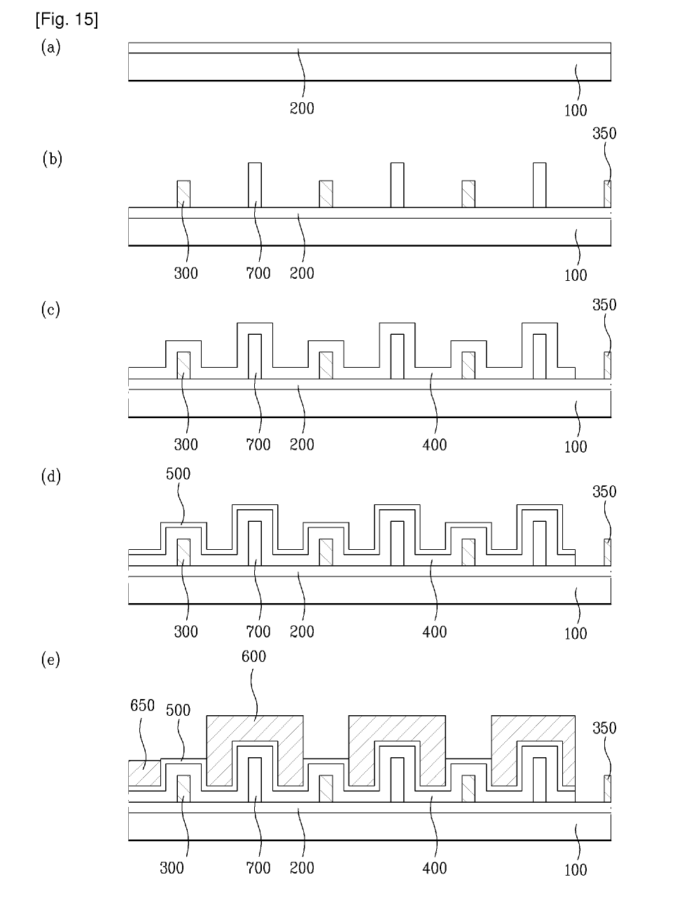

FIGS. 15A to 15E are cross section views illustrating a method for manufacturing a thin film type solar cell according to the fourth embodiment of the present invention. Hereinafter, the detailed explanation for the same parts as those of the previously explained embodiments will be omitted.

First, as shown in FIG. 15A, the front electrode layer 200 is formed on the substrate 100.

Next, as shown in FIG. 15B, the auxiliary electrode 300 and the insulating layer 700 are formed on the front electrode layer 200.

In this case, the auxiliary electrode 300 may be formed firstly, and the insulating layer 700 may be formed secondly. Instead, the insulating layer 700 may be formed firstly, and the auxiliary electrode 300 may be formed secondly.

Preferably, the insulating layer 700 and the auxiliary electrode 300 may be alternately arranged at fixed intervals along one direction.

The auxiliary electrode 300 and the first bus line 350 connected with the auxiliary electrode 300 are formed at the same time.

The insulating layer 700 is higher than the auxiliary electrode 300. As show in FIGS. 10A to 10D, the insulating layer 700 may be formed in predetermined patterns arranged at fixed intervals, wherein each pattern is formed of the insulating-material pattern with the elliptical-shaped horizontal cross section.

As shown in FIG. 15C, the semiconductor layer 400 is formed on the auxiliary electrode 300 and the insulating layer 700. The semiconductor layer 400 is not formed on the first bus line 350.

As shown in FIG. 15D, the transparent conductive layer 500 is formed on the semiconductor layer 400. The transparent conductive layer 500 is not formed on the first bus line 350.

As shown in FIG. 15E, the rear electrode 600 and the second bus line 650 are formed on the transparent conductive layer 500, thereby completing the thin film type solar cell according to the fourth embodiment of the present invention.

The rear electrode 600 may be provided above the insulating layer 700, that is, the predetermined portion between each of the auxiliary electrodes 300.

### FIFTH EMBODIMENT

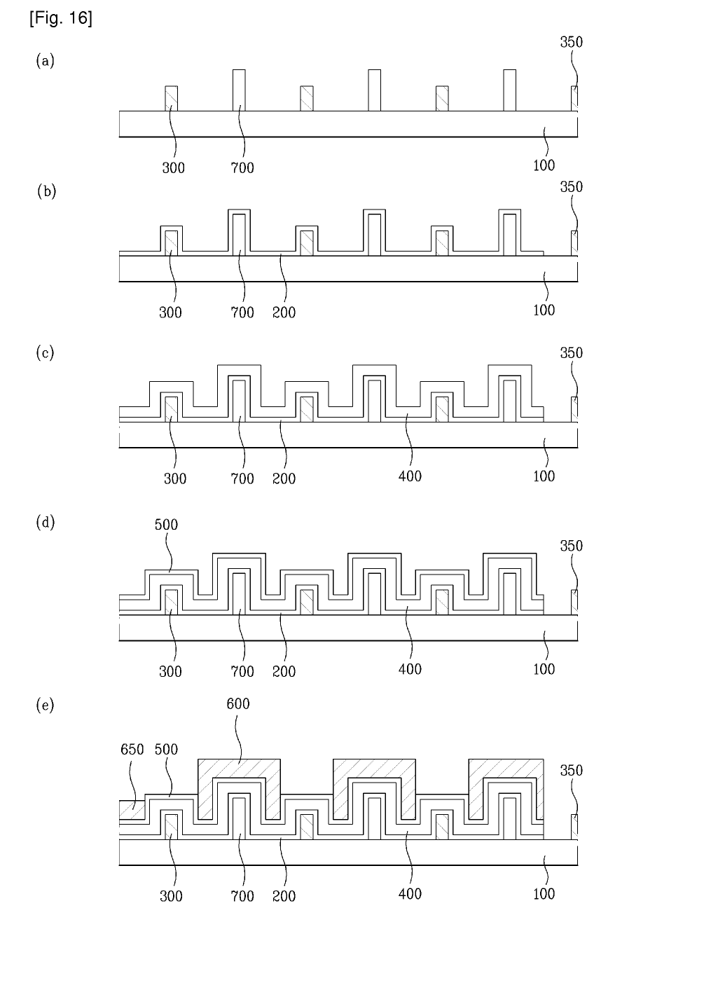

FIGS. 16A to 16E are cross section views illustrating a method for manufacturing a thin film type solar cell according to the fifth embodiment of the present invention. Hereinafter, the detailed explanation for the same parts as those of the previously explained embodiments will be omitted.

First, as shown in FIG. 16A, the auxiliary electrode 300 and the insulating layer 700 are formed on the substrate 100.

When forming the auxiliary electrode 300, the first bus line 350 is formed at the same time.

Next, as shown in FIG. 16B, the front electrode layer 200 is formed on the substrate 100, the auxiliary electrode 300, and the insulating layer 700.

Then, as shown in FIG. 16C, the semiconductor layer 500 is formed on the front electrode layer 200.

As shown in FIG. 16D, the transparent conductive layer 500 is formed on the semiconductor layer 400.

Then, as shown in FIG. 16E, the rear electrode 600 and the second bus line 650 are formed on the transparent conductive layer 500, thereby completing the thin film type solar cell according to the fifth embodiment of the present invention.

### SIXTH EMBODIMENT

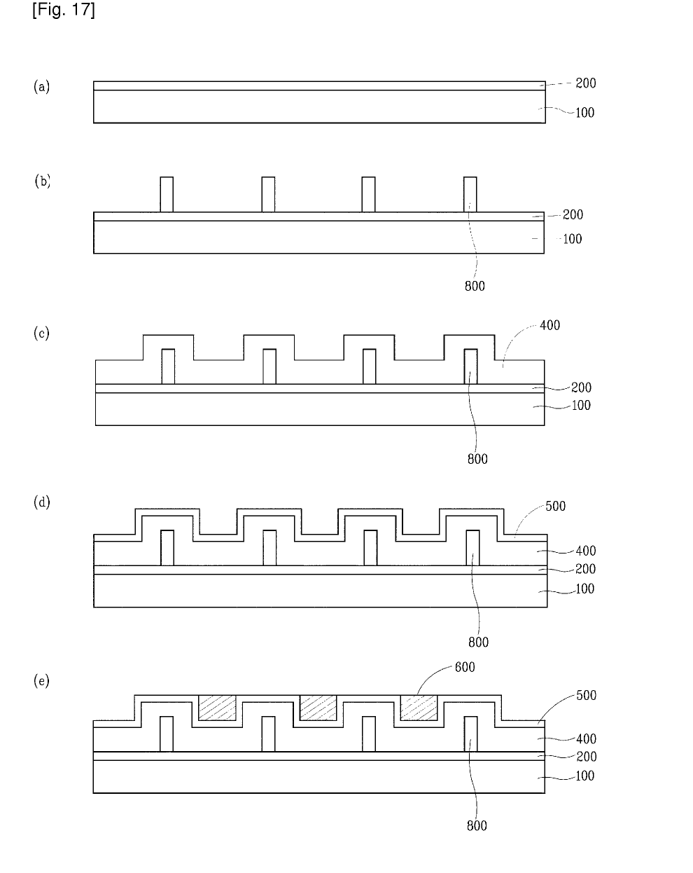

FIGS. 17A to 17E are cross section views illustrating a method for manufacturing a thin film type solar cell according to the fifth embodiment of the present invention. Hereinafter, the detailed explanation for the same parts as those of the previously explained embodiments will be omitted.

First, as shown in FIG. 17A, the front electrode layer 200 is formed on the substrate 100.

Then, as shown in FIG. 17B, the partition wall 800 is formed on the front electrode layer 200.

The partition wall 800 may be formed in the repetitive pattern suitable for dividing the thin film type solar cell into the plurality of unit cells. In more detail, the partition wall 800 may be provided in the stripe pattern as shown in FIGS. 11A and 11B, or may be provided in the grating pattern as shown in FIG. 11C.

The partition wall 800 may be formed of the transparent insulating material such as SiO₂, TiO₂, SiNₓ, SiON, or polymer by the screen printing method, inkjet printing method, gravure printing method, or micro-contact printing method.

As shown in FIG. 17C, the semiconductor layer 400 is formed on the partition wall 800.

Then, as shown in FIG. 17D, the transparent conductive layer 500 is formed on the semiconductor layer 400.

As shown in FIG. 17E, the rear electrode 600 is formed on the transparent conductive layer 500, thereby completing the thin film type solar cell according to the sixth embodiment of the present invention.

Although not shown, the partition wall 800 may be firstly formed on the substrate 100, and the front electrode layer 200 may be secondly formed on the partition wall 800.

In the method for manufacturing the thin film type solar cell according to the first embodiment of the present invention, the front electrode layer 200 may be formed on the auxiliary electrode 300. In the methods for manufacturing the thin film type solar cells according to the second and third embodiments of the present invention, the front electrode layer 200 may be formed on the auxiliary electrode 300 and the insulating layer 700.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A thin film type solar cell comprising:
a substrate;
a front electrode layer, a cell-dividing part and an insulating layer on the substrate;
a semiconductor layer on the front electrode layer, the cell-dividing part and the insulating layer; and
a rear electrode on the semiconductor layer,
wherein the cell-dividing part is comprised of an auxiliary electrode.

2. (canceled)

3. (canceled)

4. The thin film type solar cell according to claim 1, wherein the insulating layer is formed on lateral and upper surfaces of the auxiliary electrode.

5. The thin film type solar cell according to claim 1, wherein the insulating layer is formed at one lateral side of the auxiliary electrode.

6. The thin film type solar cell according to claim 1, wherein the insulating layer is formed between each of the auxiliary electrodes.

7. The thin film type solar cell according to claim 6, wherein the insulating layer is formed in a predetermined pattern with an elliptical-shaped horizontal cross section.

8. The thin film type solar cell according to claim 1, wherein the insulating layer is higher than the auxiliary electrode.

9. The thin film type solar cell according to claim 1, further comprising first and second bus lines exposed to the external, wherein the first bus line is connected with the auxiliary electrode at one side of the substrate, and the second bus line is connected with the rear electrode at the other side of the substrate.

10. The thin film type solar cell according to claim 1, wherein the auxiliary electrode is comprised of a plurality of first auxiliary electrodes arranged at fixed intervals in a first direction, and a second auxiliary electrode arranged in a second direction to connect the respective first auxiliary electrodes.

11. The thin film type solar cell according to claim 1, wherein the auxiliary electrode is formed of a predetermined material whose electric conductivity is higher than the front electrode layer.

12. A thin film type solar cell comprising:
a substrate;
a front electrode layer and a cell-dividing part on the substrate;
a semiconductor layer on the front electrode layer and the cell-dividing part; and
a rear electrode on the semiconductor layer,
wherein the cell-dividing part is formed of a partition wall.

13. The thin film type solar cell according to claim 12, wherein the partition wall is formed in a stripe or grating pattern.

14. The thin film type solar cell according to claim 1, wherein the rear electrode is comprised of a plurality of first rear electrodes arranged at fixed intervals in a first direction, and a second rear electrode arranged in a second direction to connect the respective first rear electrodes.

15. The thin film type solar cell according to claim 1, wherein the rear electrode is formed in an area between each of the cell-dividing parts.

16. The thin film type solar cell according to claim 1, further comprising a transparent conductive layer between the semiconductor layer and the rear electrode.

17. The thin film type solar cell according to claim 1, wherein the cell-dividing part is formed on the front electrode layer.

18. The thin film type solar cell according to claim 1, wherein the cell-dividing part is formed underneath the front electrode layer.

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. The thin film type solar cell according to claim 12, wherein the rear electrode is comprised of a plurality of first rear electrodes arranged at fixed intervals in a first direction, and a second rear electrode arranged in a second direction to connect the respective first rear electrodes.

38. The thin film type solar cell according to claim 12, wherein the rear electrode is formed in an area between each of the cell-dividing parts.

39. The thin film type solar cell according to claim 12, further comprising a transparent conductive layer between the semiconductor layer and the rear electrode.

40. The thin film type solar cell according to claim 12, wherein the cell-dividing part is formed on the front electrode layer.

41. The thin film type solar cell according to claim 12, wherein the cell-dividing part is formed underneath the front electrode layer.
